(19) United States
(12) Patent Application Publication
(10) Pub. No.: US 2007/0099404 A1
(43) Pub. Date: May 3, 2007

(54) Implant and anneal amorphization process

(76) Inventors: Sridhar Govindaraju, Hillsboro, OR (US); Jack Hwang, Portland, OR (US); Seok-Hee Lee, Portland, OR (US); Patrick H. Keys, Portland, OR (US); Chad D. Lindfors, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/261,843

(22) Filed: Oct. 28, 2005

(51) Int. Cl. H01L 21/265; H01L 21/4763

(52) U.S. Cl. 438/520; 438/649; 257/E29.156

(57) ABSTRACT

A method for improving a microelectronic device interface with an ultra-fast anneal process at an intermediate temperature that may be lower than those used in a dopant activation process. In one embodiment, a partial recrystalization of an amorphous silicon layer in the source drain region that is the precursor to the metal salicide reaction is disclosed. Source/drain regions are first amorphized using an implant process, then a metal layer is deposited in the source/drain region which reacts with the silicon in a salicide formation anneal. Amorphization reduces problems with metal diffusion that can occur during salicide formation anneal process, which typically occurs at a temperature significantly lower than the dopant activation temperature. The partial recrystalization reduces source/drain interfacial roughness, repairs amorphization-related defects, and reactivates dopants previously deactivated during the amorphization implant, thereby reducing the external resistance and leakage, as well as improving mobility and yield.

### BACKGROUND OF THE INVENTION

1. Field of the Invention

Embodiments of the present invention relate generally to microelectronic device processing and more specifically to methods of forming source/drain regions for microelectronic devices.

2. State of the Art

A driving force in the semiconductor based microelectronics industry is transistor scaling, which enables increases in transistor density and increased transistor performance. In each microelectronic generation, dimensions are scaled by approximately 0.7 times. As the transistor dimensions continue to shrink below 100 nm, the distinction between bulk silicon and source/drain region interfaces begin to blur, as will be understood to those skilled in the art. Improvements in the physical and chemical quality of the interface are expected to have benefits for the yield and device performance.

A key parameter in assessing device performance is the transistor current delivered for a given design voltage and off-state leakage. This parameter is commonly referred to as transistor drive current. Drive current is affected by factors that include the transistor's channel mobility and external resistance. It is desirable to increase the drive current for fixed voltage and off-state leakage.

Channel mobility refers to the mobility of carriers (i.e., holes and electrons) in the transistor's channel region. Increased carrier mobility translates directly into increased drive current. External resistance refers to resistances external to the channel and associated with the transistor's source/drain regions. External resistance includes (1) the resistances associated with the ohmic contacts (metal to semiconductor and semiconductor to metal), (2) the resistance within the source/drain and source/drain extension (tip) regions, and (3) the resistance of the region between the channel and tip region. To the extent that any one or more of the individual resistances associated with external resistance can be reduced, linear and saturation drive currents correspondingly increase.

Turning to FIG. 1, a cross-sectional view of portions of a microelectronic device 100 is shown. Microelectronic device 100 includes a gate 102 overlying a gate dielectric 104, spacers 106 adjacent the gate 102 and gate dielectric 104, source/drain regions 108 and source/drain extensions (tip regions) 110 formed in/on a microelectronic substrate 101 (such as a silicon-containing substrate), and salicide regions 112 formed on/in the source/drain regions 108. Salicide region 112 can be, for example, a metal salicide formed using conventional techniques. Typically, this includes depositing a metal, such as nickel, cobalt, or the like over the microelectronic device, heating to react the metal and exposed silicon regions (thereby forming the metal silicide), and then removing unreacted metal to form the salicide.

One concern with the process of forming such a microelectronic device 100 involves the step of reacting the metal and exposed silicon regions to form the silicide. More specifically, the heating used to cause the reaction can promote diffusion of metal along grain boundaries and extended crystal defects in the silicon substrate 101, thereby forming conductive diffusion metal pipe defects 116. To the extent that the pipe defects 116 extend between adjacent source and drain regions or intersect with each, source-to-drain leakage paths can be produced (shown in area 118). These paths can compromise the microelectronic device's yield, performance, and/or reliability.

As shown in FIG. 2, one approach taken to reduce pipe defects includes converting the monocrystalline source/drain regions to an amorphous microelectronic material prior to forming the salicide regions 212. The amorphous state is indicated by the dot-pattern shading in the deep source/drain regions 208. The amorphized regions reduce the density of some source crystalline defects and the diffusivity of the metal, thereby retarding the formation/proliferation of pipe defects 116 (shown in FIG. 1).

The amorphization process presents other integration concerns. The salicide process typically occurs after the junction implants have been annealed at high temperature to activate dopants and remove defects. As a byproduct, the amorphization implant introduces point defects and deactivates the dopants in the adjacent unamorphized regions which reduces mobility. In addition, the implant process used to create the source/drain amorphous region will result in a rough amorphous/crystalline interface. This can have undesirable defects when annealed in the low temperature salicide formation process. For example, these defects can nucleate the formation of metal pipe defects during the salicide formation step. Following salicide formation, the amorphous region may recrystallize, but it is not possible to re-anneal the wafer to the high temperatures needed to remove all defects due to constraints of the presence of salicide. The final process is a compromise between yield and transistor performance.

Therefore, it would be advantageous to devise a fabrication method which reduces the negative impact of the salicide process on device performance.

### BRIEF DESCRIPTION OF THE DRAWINGS

While the specification concludes with claims particularly pointing out and distinctly claiming that which is regarded as the present invention, the advantages of this invention can be more readily ascertained from the following description of the invention when read in conjunction with the accompanying drawings in which:

FIG. 1 illustrates a cross-sectional view of a microelectronic device that shows pipe defects that can be produced as a result of heating during silicide/salicide processing, as known in the art.

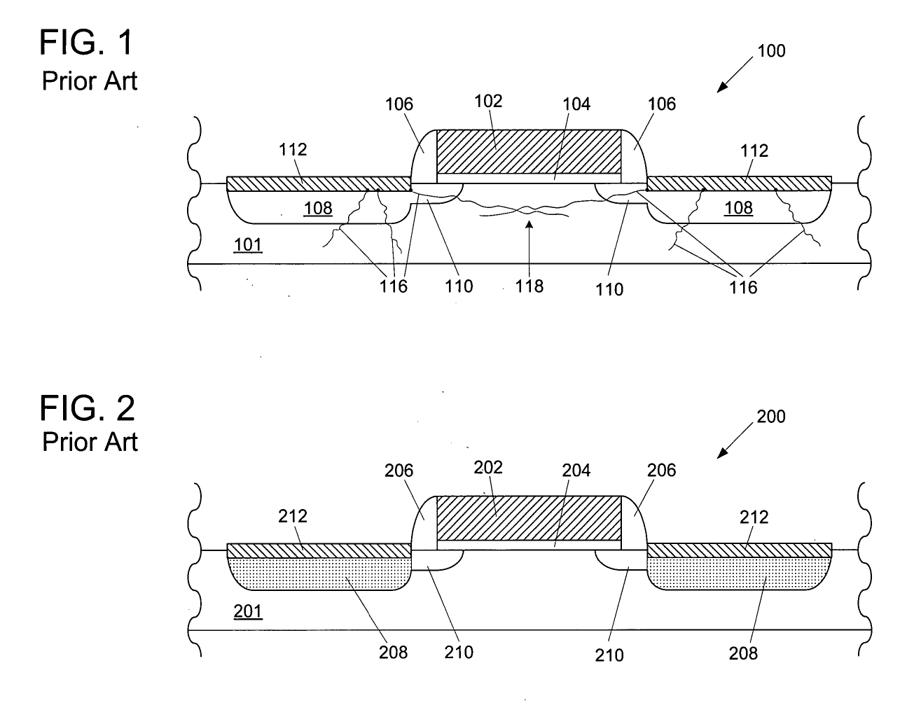

FIG. 2 illustrates a cross-sectional view of a microelectronic device that shows the use of amorphized source/drain and tip regions to reduce pipe defect densities, as known in the art.

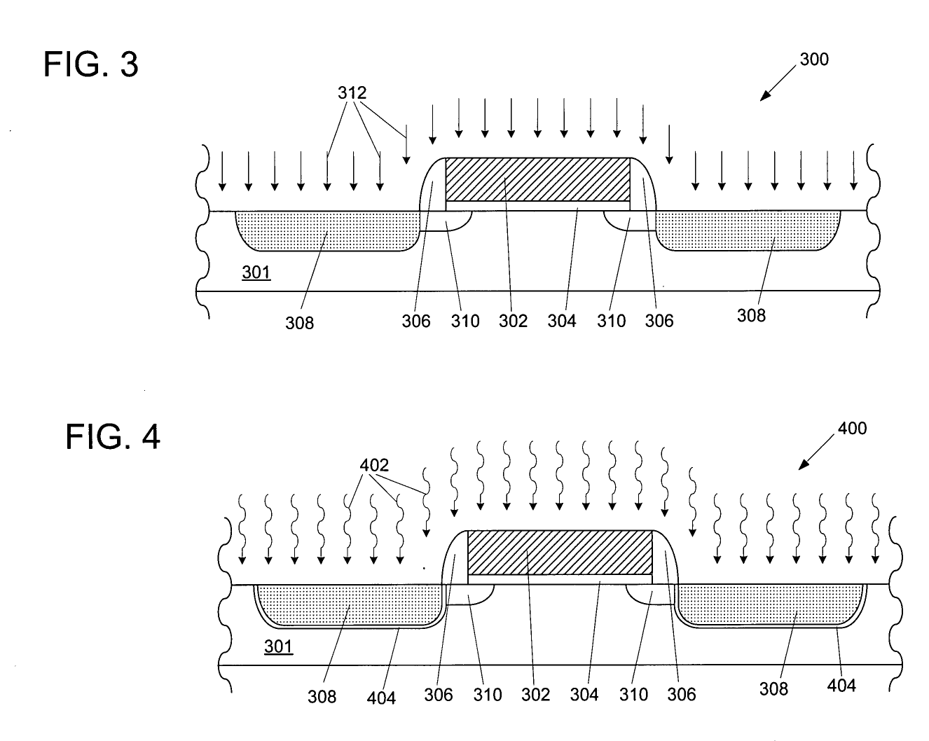

FIGS. 3-6 illustrate cross-sectional views showing the formation of a microelectronic device in accordance with one embodiment of the present invention.

FIG. 7 illustrates a graph showing the impact that various embodiments of the present invention can have on drive current gain and crystalline regrowth.

FIGS. 8a and 8b illustrates SEM of roughness improvement at the interface between the substrate and the source/drain regions.

FIG. 9 illustrates a graph showing generalized curves with regard to improvements in device leakage.

It will be appreciated that for simplicity and clarity of illustration, elements illustrated in the drawings have not necessarily been drawn to scale. For example, the dimensions of some of the elements are exaggerated relative to other elements for clarity. Further, where considered appropriate, reference numerals have been repeated among the drawings to indicate corresponding or analogous elements.

### DETAILED DESCRIPTION OF THE ILLUSTRATED EMBODIMENT

In the following detailed description, an integration scheme is disclosed for the fabrication of source/drains in microelectronic devices. Reference is made to the accompanying drawings within which are shown, by way of illustration, specific embodiments by which the present invention may be practiced. It is to be understood that other embodiments may exist and that other changes may be made without departing from the scope and spirit of the present invention.

In addition, specific details such as specific materials are set forth herein in order to provide a thorough understanding of the present invention. However, it will be apparent to one skilled in the art that the present invention may be practiced without these specific details. In other instances, well known processing steps and/or microelectronic device elements have not been described in detail in order not to unnecessarily obscure the present invention. For example, well-known cleaning steps, protective layers, and/or interconnecting circuitry often used in the fabrication of microelectronic devices, are not described.

The terms on, above, below, and adjacent as used herein refer to the position of one layer or element relative to other layers or elements. As such, a first element disposed on, above, or below a second element may be directly in contact with the second element or it may include one or more intervening elements. In addition, a first element disposed next to or adjacent a second element may be directly in contact with the second element or it may include one or more intervening elements.

The present invention utilizes a pre-heat and a low thermal budget, ultra-fast anneal to improve the interface between the source/drain region and the microelectronic substrate, reactivate dopants, and to anneal out certain defects with minimal impact to the transistor junctions. The interface is not limited to silicon, but could be any interface or component in the microelectronic device manufacturing process. The temperature for the specific application is customized for the particular phase transformation and may be different than those used to activate dopants

In one embodiment, a combination implant and anneal is used to create an amorphous layer in the transistor's source/drain regions. The implant first converts the source/drain regions from monocrystalline semiconductor material to an amorphous semiconductor material and thereby retards metal diffusion during subsequent reactions between the metal and semiconductor material. In one embodiment the semiconductor material is silicon and the reaction between the metal and silicon forms a metal silicide. In one embodiment, the annealing process is an ultra-fast anneal. Because the anneal is ultra-fast, it minimally impacts the amorphous regions depth's profile while still annealing to an elevated temperature. At the same time, the low thermal budget of the process minimizes diffusion of the implanted dopant profiles.

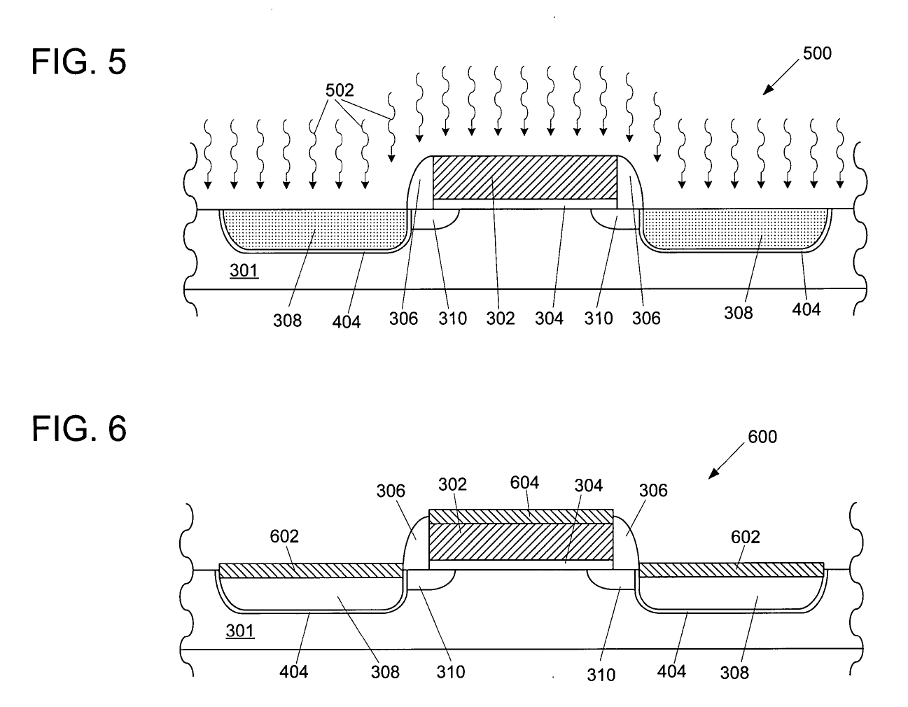

Benefits of this process include reducing interfacial roughness of the amorphous/crystalline region and reactivation of deactivated dopants in the tips and channel caused by implant straggle. Improvements in the interfacial roughness can reduce sites that may nucleate metal pipe defects, resulting in improved yield process margin for the salicide process. Reactivation of the source drain extensions can reduce the external resistance and increases drive current at a given voltage and off-state leakage. Reactivation of implants that control the threshold voltage and short channel effects can reduce transistor leakage and improve mobility. These and other embodiments will now be discussed in further detail with respect to FIGS. 3-5, below, which illustrate in cross-sectional diagrams, formation of salicide in accordance with an embodiment of the present invention. The drawings however, should not be taken to be limiting, as they are intended primarily for the purpose of explanation and understanding.

Shown in FIG. 3 is a cross-sectional view of a microelectronic device 300. The microelectronic device 300 (such as a transistor) includes a gate 302 overlying a gate dielectric 304, sidewall spacers 306 formed adjacent sidewalls of the gate 302 and gate dielectric 304, and source/drain regions 308 and extension regions (tips) 310 formed on/in microelectronic substrate 301. In one embodiment, the microelectronic substrate is a monocrystalline silicon substrate. As known to one of ordinary skill in the art, the tips 310 can be formed using a conventional implant process prior spacer 306 formation and the deep source/drain regions can be formed using a conventional implant process after spacer 306 formation. Then, as indicated by the arrows 312, after the tips and deep source drains have been formed, the microelectronic device 300 is annealed with a high temperature anneal to activate the dopants.

The salicide portion of the process begins with ion implantation using known processes (e.g., using germanium, nitrogen, silicon, or the like) to amorphize crystalline source/drain and tip regions in the substrate. Here, amorphization is indicated by the dot-pattern shading in areas 308. Amorphization can reduce the density of pipe defects commonly found during the formation of reactive metal silicides, such as nickel silicide and cobalt silicide.

Amorphization can also increase external resistance in the microelectronic device through the creation of defects and dopant deactivation. Dopant deactivation requires an increase in the dopant concentration necessary to achieve the same level of activation. The cause is multifaceted, but is believed to be related to encroachment of defects under the spacers and channel (i.e. in the tips) caused by implant straggle as a result of amorphization. The microelectronic device performance is reduced by an increase in external resistance and thereby decreasing linear and saturation drive currents.

Similarly, the same encroachment of defects can also result in the deactivation of the counter-doping implants known as halo or threshold voltage implants. These are low dose implant of the opposite doping type from the tips/source drain extension used to control leakage. Deactivation of dopants requires a larger implant dose to achieve the same electrical characteristics. These deactivated dopants can degrade mobility and increase junction leakage. In some instances, the spatial dependence of this deactivation can not be simply compensated only by a dose increase. The defects are not completely annealed out during subsequent conventional thermal processing due to thermal budget constraints of the salicide and can result in mobility degradation and increased transistor leakage.

Referring now to FIG. 4, in accordance with one embodiment, the microelectronic device 300 of FIG. 3 is next brought to an intermediate temperature, for example between about 150 and 500 degrees Celsius for a duration of time from seconds to hours (e.g., about 10 seconds to 5 hours). The time versus temperature is a quantity that is to be optimized for a particular process. It is, of course, understood that there is no true upper limit to the time duration for bring and holding the microelectronic device 300 to the intermediate temperature. The heating of the microelectronic device 300 of FIG. 3 to an intermediate temperature is represented by wavy lines 402 to form a pre-heated microelectronic device 400, as shown in FIG. 4. The pre-heated microelectronic device 400 of FIG. 4 is then brought to a final peak temperature using a rapid temperature jump, such as by way of example, an ultra-fast anneal such as a flash lamp or laser annealing process at a temperature in a range of about 500 to 1300 degrees Celsius and for a time less than about 1 second, and may be significantly less than 1 second (for example between about 0.1 to 15 milliseconds). The annealing of the pre-heated microelectronic 400 of FIG. 4 to an intermediate is represented by wavy lines 402 to form an annealed microelectronic device 500, as shown in FIG. 5.

The intermediate anneal temperature and time may be optimized to allow a certain amount of low temperature rearrangement of the amorphous layer to improve the activation by the ultra-fast process. It has also been found that lower leakage is achieved by increasing the duration of time that the wafer resides at the intermediate temperature. For example, holding the wafer at a temperature of 200 degrees Celsius for 1 minute as opposed to 30 seconds can reduce the leakage by about one-half to one-third. In this particular embodiment, the low temperatures used for the amorphous layer anneal is significantly lower

It has been found that processing the microelectronic device (e.g., entire microelectronic wafer) with only the intermediate temperature or only the ultra-fast anneal separately will not achieve the same effect for dopant reactivation as the combined process. The low temperature rearrangement of the amorphous layer can be broken up into separate processes, both during the ion implantation or in a separate reactor prior to the ultra-fast anneal. This rearrangement is critical at the lower temperature since the ultra-fast anneal allows little diffusion. In addition, the actual peak and intermediate temperature prior to the ultra-fast anneal is constrained by having minimal amount of recrystallization of the amorphous layer while still being hot enough to anneal out the point defects and reactivating the dopants.

Annealing recrystallizes portions of the source/drain regions 404 and thereby preferentially reactivates dopants adjacent the source/drain and tip region junctions (i.e., interface between the bulk microelectronic substrate 101 and the source/drain regions 308). This provides a means for modulating the amount/degree of silicon amorphization along the active area's peripheral boundaries and varying encroachment of the amorphous regions. This has a corresponding effect on reducing the external resistance and leakage associated with the tip-to-channel resistance. The degree of recrystallization can vary according to the increase in drive current desired. However it may be preferable to recrystallize silicon regions only to the extent that the amorphized regions still reliably prevent the formation of pipe defects.

Annealing is also believed to advantageously reduce the density of otherwise unrepairable amorphization defects in the amorphized and interfacial regions between 308 and 310. These interfacial defects can nucleate conductive diffusion metal pipe defect formation and thus decrease yield, as previously discussed. This also has a corresponding effect on reducing the external resistance associated with the internal source/drain and tip resistances. In addition, annealing can reduce the surface roughness by repairing surface damage caused by the amorphization implant. This can reduce ohmic contact resistance at the contact-to-source/drain interface, provide increased process margin to prevent conductive diffusion metal pipe defect formation, improve diode characteristics, chip yields, and the like.

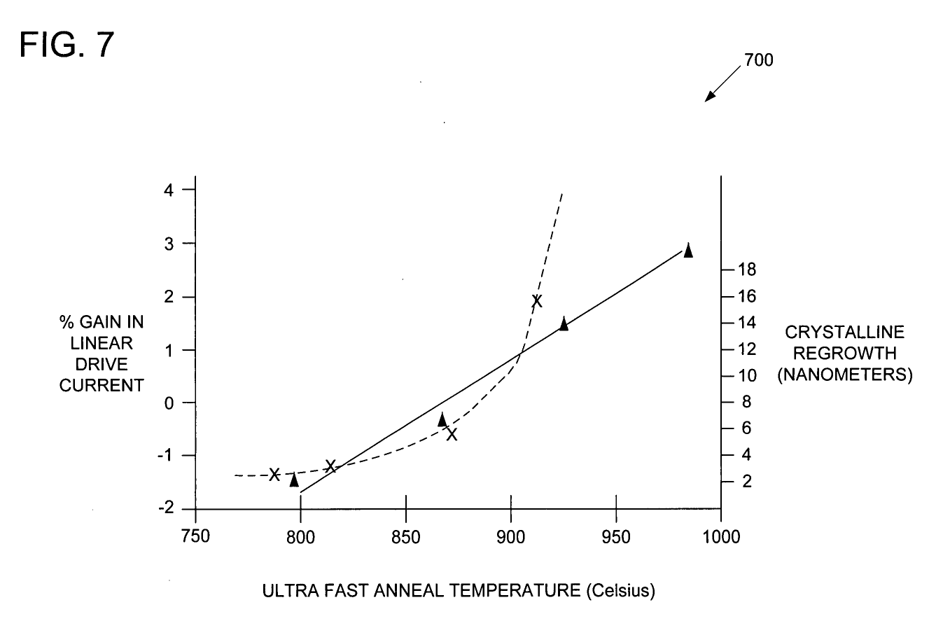

Shown in FIG. 7 is a graph 700 that plots percentage gain in linear drive current and crystalline regrowth as functions of anneal temperature. As indicated here, varying the anneal temperature between approximately 780 and 920 degrees Celsius can result in crystalline regrowth under spacers that ranges from approximately 3 to 15 nanometers. Also, varying the anneal temperature between approximately 800 degrees Celsius and 980 degrees Celsius can result in a significant gain in transistor performance measured both by drive current and oscillator frequency. As indicated here, a correlation exists between annealing temperature and linear drive current. The increased linear drive current may be attributed to the ability of an ultrafast anneal to reduce: (1) interfacial amorphization defects, (2) the amount of amorphous region encroachment under the spacer, and/or (3) the amount of source/drain surface roughness. One of ordinary skill will appreciate that in addition to anneal temperature, anneal time is another factor that can potentially influence these results.

Turning now to FIG. 6, the microelectronic device 500 shown in FIG. 5 has been further processed to form salicide regions over exposed silicon regions. First silicide regions 602 are formed over amorphized source/drain regions 308 and a second salicide region 604 may optionally be formed over the gate 302. In one embodiment, the first salicide regions 602 and second salicide region 604 can be formed using conventional processing, whereby a metal (such as titanium, tantalum, platinum, molybdenum, cobalt, nickel or the like) is deposited over the microelectronic device 500 of FIG. 5, and then reacted with the exposed silicon areas of the source/drains 308 and gate electrode 302 to form a silicide, thereby forming microelectronic device 600. The silicide formation may also recrystallize the substantially all of the amorphized source/drain regions 308, as illustrated by the lack of dot-patterned shading in FIG. 6. Following the silicide formation, a selective etch process removes unreacted metal thereby forming the salicide. However, unlike conventional processes for forming silicide/salicide regions, the embodiments disclosed herein forms the salicide not only with reduced diffusion metal pipe defects, but also with increased drive current as compared to prior art microelectronic devices.

Processing from this point on to fabricate the microelectronic device and its associated circuitry is considered conventional to one of ordinary skill. Any number of interlayer dielectrics, insulation structures, microelectronic structures, conductive structures, and the like can be formed overlying the microelectronic device 600 to fabricate integrated circuits of varying complexity.

In the various embodiments discussed herein, methods for forming salicided source/drain regions have been disclosed. In one embodiment amorphized source/drain regions are annealed prior to siliciding the source/drain regions. Annealing the amorphized regions of a microelectronic device prior to silicidization can advantageously recrystallize portions of the amorphous region under the spacer, repair otherwise unrepairable amorphization related defects in the source/drain and tip regions, and/or reduce source/drain amorphous surface roughness. All while permitting the amorphized regions to continue to retard pipe defect formation during construction of the salicide layer. The anneal time and temperature can be optimized to maximize drive current, minimize pipe defect densities and leakage by reactivating amorphized regions specifically to the amount desired for specific microelectronic devices. The ability to incorporate one or more of these embodiments can improve overall transistor performance increasing drive current at a given comparable voltage.

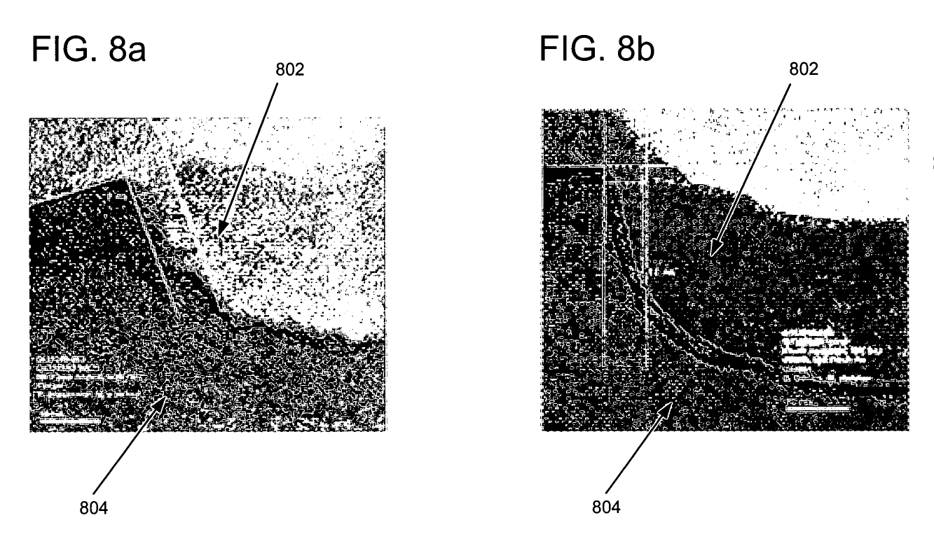

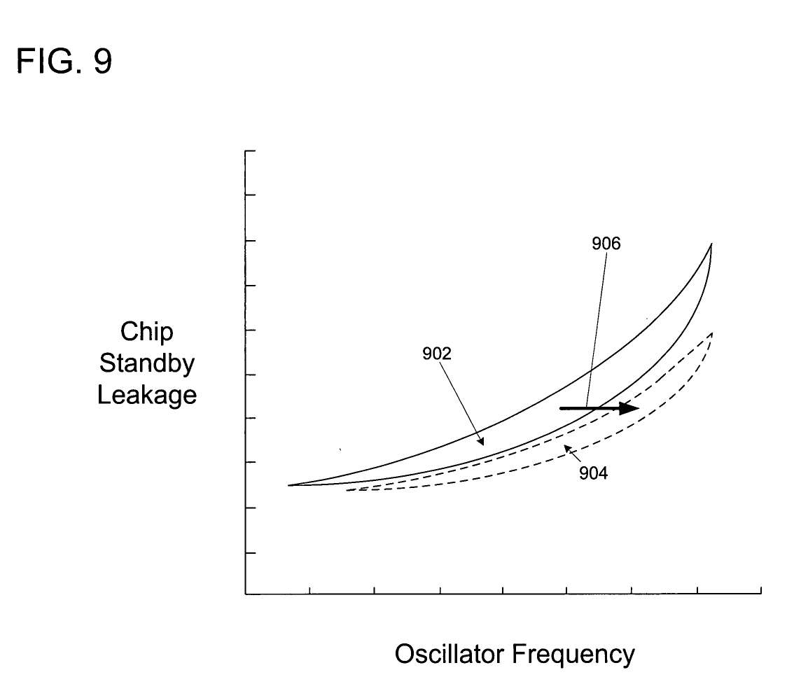

The combined low temperature amorphous rearrangement with low temperature ultra-fast anneal to solve the issues described with regard to salicide formation has resulted in surprising results which allows annealing without little or no dopant diffusion or yield loss and results in transistor performance enhancements. First, a reduction in interface roughness between the source/drain region 802 and the microelectronic substrate 804 caused by the amorphization implant is seen, as shown in FIG. 8a (without using the process of the present invention) and FIG. 8b (using the process of the present invention). Second, a significant reduction of pipe defects (as much as an order of magnitude at the limits of the process window) has been observed. Third, improvements in the activation of the threshold voltage implant. These improvements can combine into improvements in the overall standby leakage of a chip for fixed oscillator frequency, as demonstrated in FIG. 9.

FIG. 9 represents the distribution of the chip standby leakage versus the oscillator frequency for a wafer. The closed shape is meant to illustrate the data zone distribution of the device parameters across a wafer, which are a result of process variations. Solid line distribution 902 illustrates the approximate data zone for oscillator frequency (e.g., chip speed) vs. chip standby leakage in a device which does not utilize the present invention. Dashed line 904 illustrates the approximate data zone for oscillator frequency vs. chip standby leakage in a device which utilizes the present invention. The present invention results in a shift 906 in leading edge performance of the device, such that higher frequencies can be achieved for fixed leakage. In addition, the trailing edge of leakage for fixed frequency is improved resulting in a positive shift of the median to higher frequency for fixed leakage. It is, of course, understood that these are not the only improvements which may be seen with the utilization of the present invention.

The various implementations described above have been presented by way of example only and not limitation. The anneal process is considered to be complementary to the amorphization implant. Novel techniques may be used in conjunction such as an angled implant or heated implant chuck. While annealing disclosed herein refers to using a flash anneal process to recrystallize active areas under the spacer, one of ordinary skill appreciates that other annealing processes capable of global or local heating can similarly be used. For example, pulse-laser thermal annealing can be performed by raster scanning the microelectronic substrate to globally anneal it or by projecting the pulsed beam directly onto individual transistors or source/drain regions to locally anneal specific regions on the microelectronic substrate. Instead of a flash lamp, an arc lamp may also be used.

Although the present invention is focused on modifying/improving the results of an amorphization process and is described in terms of the formation of source/drain regions with silicide layer for transistor, the invention is not so limited. As will be understood to those skilled in the art, the present invention can be utilized for any number of phase transformations, including, but not limited to, metal grain boundaries, surface state rearrangement, and the like.

Having thus described in detail embodiments of the present invention, it is understood that the invention defined by the appended claims is not to be limited by particular details set forth in the above description, as many apparent variations thereof are possible without departing from the spirit or scope thereof.

What is claimed is:

1. A method for forming a microelectronic device comprising:
forming source/drain regions in a microelectronic substrate;
amorphizing said source/drain regions;
recrystallizing at least one of portion of said source/drain regions;
depositing a metal material over said amorphized source/drain regions; and
heating said microelectronic substrate to convert portions of said metal and portions of said amorphized source/drain regions to a silicide.

2. The method of claim 1, wherein amorphizing said source/drain regions is accomplished by implanting said source/drain regions with ions selected for the group consisting of germanium, argon, silicon, and nitrogen.

3. The method of claim 1, wherein recrystallizing at least one portion of said source/drain region is accomplished by annealing said source/drain regions.

4. The method of claim 1, wherein annealing said source/drain regions comprises pre-heating said source/drain regions followed by rapid thermal annealing said source/drain regions.

5. The method of claim 4, wherein pre-heating said source/drain regions comprises heating said source/drain regions to a temperature between about 180 and 500 degrees Celsius.

6. The method of claim 4, wherein said rapid thermal annealing said source/drain regions comprises heating to a temperature in a range of about 500 to 1300 degrees Celsius.

7. The method of claim 4, wherein said rapid thermal annealing said source/drain regions comprises rapid thermal annealing for a duration of time less than one second.

8. The method of claim 7, wherein said rapid thermal annealing said source/drain regions comprises rapid thermal annealing for a duration of time between about 0.1 to 15 milliseconds.

9. The method of claim 1, wherein recrystallizing at least one portion of said source/drain region comprised recrystallizing at least one portion of said source/drain region adjacent the source/drain junctions.

10. The method of claim 1, wherein recrystallizing at least one portion of said source/drain region further comprises reactivating dopants within said source/drain regions.

11. The method of claim 1, wherein heating said microelectronic substrate to convert portions of said metal and portions of said amorphized source/drain regions to a silicide further includes substantially recrystallizing said amorphized source/drain regions.

12. A method for forming a microelectronic device comprising:
forming source/drain regions in a microelectronic substrate;
amorphizing said source/drain regions;
recrystallizing at least one of portion of said source/drain regions;
depositing a metal material over said amorphized source/drain regions; and
converting portions of said metal and portions of said amorphized source/drain regions to a silicide; and
reactivating said source/drain regions.

13. The method of claim 12, wherein amorphizing said source/drain regions is accomplished by implanting said source/drain regions with ions selected for the group consisting of germanium, argon, silicon, and nitrogen.

14. The method of claim 12, wherein recrystallizing at least one portion of said source/drain region is accomplished by annealing said source/drain regions.

15. The method of claim 14, wherein annealing said source/drain regions comprises pre-heating said source/drain regions followed by rapid thermal annealing said source/drain regions.

16. The method of claim 15, wherein pre-heating said source/drain regions comprises heating said source/drain regions to a temperature between about 180 and 500 degrees Celsius.

17. The method of claim 15, wherein said rapid thermal annealing said source/drain regions comprises heating to a temperature in a range of about 500 to 1300 degrees Celsius.

18. The method of claim 15, wherein said rapid thermal annealing said source/drain regions comprises rapid thermal annealing for a time duration of less than one second.

19. The method of claim 18, wherein said rapid thermal annealing said source/drain regions comprises rapid thermal annealing for a time duration between about 0.1 to 15 milliseconds.

20. The method of claim 12, wherein recrystallizing at least one portion of said source/drain region comprised recrystallizing at least one portion of said source/drain region adjacent the source/drain junctions.

21. The method of claim 12, wherein recrystallizing at least one portion of said source/drain region further comprises reactivating dopants within said source/drain regions.

22. The method of claim 12, wherein converting portions of said metal and portions of said amorphized source/drain regions to a silicide, and reactivating said source/drain regions comprise heating said microelectronic substrate.

23. A method for forming a microelectronic transistor comprising:
forming a gate on a microelectronic substrate with a gate dielectric disposed therebetween;
forming source/drain regions in a microelectronic substrate on opposing sides of said gate;
amorphizing said source/drain regions;
recrystallizing at least one of portion of said source/drain regions;
depositing a metal material over said amorphized source/drain regions; and
heating said microelectronic substrate to convert portions of said metal and portions of said amorphized source/drain regions to a silicide.

24. The method of claim 23, wherein amorphizing said source/drain regions is accomplished by implanting said source/drain regions with ions selected for the group consisting of germanium, argon, silicon, and nitrogen.

25. The method of claim 23, wherein recrystallizing at least one portion of said source/drain region is accomplished by annealing said source/drain regions.

26. The method of claim 25, wherein annealing said source/drain regions comprises pre-heating said source/drain regions followed by rapid thermal annealing said source/drain regions.

27. The method of claim 26, wherein pre-heating said source/drain regions comprises heating said source/drain regions to a temperature between about 180 and 500 degrees Celsius.

28. The method of claim 26, wherein said rapid thermal annealing said source/drain regions comprises heating to a temperature in a range of about 500 to 1300 degrees Celsius.

29. The method of claim 26, wherein said rapid thermal annealing said source/drain regions comprises rapid thermal annealing for a duration of time less than one second.

30. The method of claim 29, wherein said rapid thermal annealing said source/drain regions comprises rapid thermal annealing for a duration of time between about 0.1 to 15 milliseconds.

31. The method of claim 23, wherein recrystallizing at least one portion of said source/drain region comprised recrystallizing at least one portion of said source/drain region adjacent the source/drain junctions.

32. The method of claim 23, wherein recrystallizing at least one portion of said source/drain region further comprises reactivating dopants within said source/drain regions.

33. The method of claim 23, wherein heating said microelectronic substrate to convert portions of said metal and portions of said amorphized source/drain regions to a silicide further includes substantially recrystallizing said amorphized source/drain regions.
